(19) United States
(12) Patent Application Publication
(10) Pub. No.: US 2004/0262169 A1
(43) Pub. Date: Dec. 30, 2004

(54) Method and device for carrying out membrane purification

(76) Inventors: Christian Hying, Rhede (DE); Franz-Felix Kuppinger, Marl (DE); Gerhard Horpel, Nottuln (DE); Bernd Penth, Lebach (DE)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/297,581

(22) PCT Filed: Jun. 29, 2001
(86) PCT No.: PCT/EP01/07493

(30) Foreign Application Priority Data
Jul. 14, 2000 (DE) 100 34 386.4

(51) Int. Cl. C25B 9/00; C30B 7/12; B01D 17/06

(52) U.S. Cl. 205/687; 204/242; 205/751

(57) ABSTRACT

A method and device for carrying out electrofiltration. Electrofiltration is a commonly known method, which is frequently used in industry for purifying suspensions, such as wastewater resulting from manufacturing processes. Conventional devices used for carrying out electrofiltration have the drawback that large amounts of expensive metals such as titanium, gold, iridium, platinum, and the like have to be used as counter-electrodes to the membrane electrodes. The method and device improve the filtration results compared to those of conventional filtration methods and modules without requiring the use of large amounts of expensive metals for the counter-electrodes. To this end, in the method the membrane electrodes are displaced, and a device carries out the method. The method and device can be used for separating substances.

A process and an apparatus for electrofiltration are claimed.

The separation of mixtures of substances is a problem frequently occurring in the industrial production of substances. Particularly frequently, liquid phases are produced which contain solids. These solids which are present in part as very small solid particles in the liquid phases must frequently be removed from the liquids before these can be further processed. A separation task of this type exists, for example, in the beverage industry, where juices must be separated from very fine solid constituents, or in the cleanup of waste waters. Frequently, in the industrial production of plastics, emulsions or latices are produced, in which the plastic is very finely distributed in a solution. In this case the plastic can be separated from the liquid by filtration, in particular by micro- or ultrafiltration. The retentate can be fed to further workup.

To separate mixtures of substances, membranes have long been used. In the case of synthetic membranes, a distinction is made between organic and inorganic membranes.

Customarily membranes made of plastics or inorganic components, for example oxides, are used. In the known processes in which these membranes are used, for example filtration, there is always the problem that the membranes plug after a relatively short service time. In the case of classical cross-flow filtration, owing to deposits on the membrane surface, there is a decrease with time of the transmembrane permeate flux, that is to say the rate at which substance flows through the membrane at constant pressure becomes lower.

This is caused by a secondary flow perpendicular to the wall, since product is taken off through the filter pores. The solid is transported by convection to the wall or membrane surface, retained and also deposited there. Although, via the high overflow velocity in the membrane modules, an attempt is made to keep the solid still in suspension, in the vicinity of the wall, within the laminar boundary layer, the solid can no longer be detached. As a result the passage of substance through the membrane is considerably decreased. The membranes must be replaced and either laboriously cleaned or disposed of.

In some commercially available membrane filtration systems, the cross-flow effect is not achieved by a high circulation pump output, but the necessary flow rate is effected by a rotating agitator which sweeps over the membrane surface. Such apparatuses are distributed, for example, by the Valmet-Flotec company. With these membrane filtration systems also, owing to deposits on or in the membrane a decrease with time of the transmembrane permeate flux also occurs, that is to say the rate at which substance flows through the membrane at constant pressure becomes lower.

With sufficiently stable ceramic membranes, for example in the case of tubular membranes made of aluminum oxide, the backwash principle has established itself. At periodic intervals of time, the direction of flow is abruptly reversed for a short time by applying a pressure pulse from the reverse side. However, this principle has the disadvantage of being able to be used effectively only in the case of liquid filtration. Furthermore, the membranes are greatly mechanically loaded and, finally, only a portion of the deposits are successfully removed.

A further possibility for cleaning membranes is the electrofiltration process. Processes and apparatuses for electrofiltration have long been known in the prior art. Thus, for example, in EP 0 165 744, EP 0 380 266 and EP 0686 420 processes are claimed which cause gas bubbles to be formed on the filter for cleaning a filter by applying a voltage and carrying out electrolysis. The gas bubbles clean the filter surface so that longer filter service times are achieved.

WO 99/15260 also describes a process for separating mixtures of substances by means of a material permeable to the substance. In this process, it is proposed to use the material as what is termed a membrane electrode and to clean this membrane by short-time application of an electrical voltage, via the gas bubble development forming in aqueous solutions in this case. In this process also, a counterelectrode of the size of the membrane electrode is necessary which, as is generally known, preferably consists of a noble metal.

To achieve gas bubble formation which is sufficient and uniform over the entire surface area of the membrane electrode, with all of these processes and apparatuses it is necessary to keep the distance between the counterelectrode and membrane electrode as small as possible. At the same time the distance between all points of the membrane electrode and the counterelectrode must be as equal as possible in order to achieve uniform intensity of gas bubble development.

The processes described have the disadvantage that, to achieve a uniform gas bubble development, the size of the area of the counterelectrode must virtually correspond to the size of the area of the membrane electrode used. This requires a high material input. Since, as counterelectrode material, usually expensive metals, for example titanium, iridium, platinum, palladium and gold, are used, a high material input simultaneously means high costs. Some attempts are being made to reduce these costs by using expanded metal electrodes or grid electrodes. Such electrodes frequently have a basic structure of titanium which is coated with mixed oxides of metals. Such electrode materials may be obtained, for example, from Heraeus, Degussa-Hüls or Metakem.

It was therefore an object of the present invention to provide a process and an apparatus in which the material expenditure for the counterelectrode is less and an improved filtration efficiency can be achieved.

Surprisingly it has been found that using a process according to claim 1, in which the membrane electrode moves, the material expenditure can be considerably decreased. At the same time, the filtration efficiency can be improved with respect to conventional processes and apparatuses.

The present invention therefore relates to a process according to claim 1 for electrofiltration in which a membrane electrode is cleaned by gas bubble development, which is characterized in that the membrane electrode used is moved.

The present invention also relates to an apparatus according to claim 12 for electrofiltration, which is characterized in that it comprises at least one rotating membrane electrode and at least one counterelectrode which has a smaller shape or outline than the membrane electrode. The inventive process has the advantage that longer filter service times can be achieved with simultaneous improvement in filtration efficiency.

The inventive apparatus has the advantage that a considerably smaller counterelectrode can be used than with conventional apparatuses, and as a result of this considerable material saving, the costs of the apparatus are considerably less than in the case of conventional apparatuses of the prior art.

The inventive process for the electrofiltration of mixtures of substances is based on the cross-flow principle in combination with electrofiltration in which a membrane electrode is cleaned by gas bubble development. In the conventional cross-flow systems, with time, as a result of fouling or other processes, a drop in filtration efficiency occurs at the membrane surface. If the filtration efficiency decreases in the inventive apparatus below a defined limiting value, the membrane surfaces are cleaned by applying an electrical current.

In contrast to the known combined processes in which attempts are made, by a high overflow rate in the membrane modules, to keep the solid in suspension, in the inventive process the membrane electrode is moved and in this manner an attempt is made to keep the majority of the solids in suspension.

The membrane electrode is moved not only during the filtration but also during the cleaning operation.

It can be advantageous to reduce, during the cleaning operation, the pressure at which the liquid to be filtered is pressed against the retentate side of the membrane electrode. Preferably, the pressure conditions during the cleaning operation are set in such a manner that the pressure on the retentate side of the membrane electrode is identical to that on the permeate side of the membrane electrode. It can be advantageous to set the pressure on the permeate side of the membrane electrode during the cleaning operation higher than on the retentate side in order to generate a stream from the permeate side to the retentate side of the membrane electrode, which can support the cleaning process in which solid particles detached by gas bubble development are carried away from the membrane electrode. After cleaning has been carried out, the pressure conditions are reestablished to conditions which are optimum for filtration. Customary pressures during filtration are, for example, a feed pressure of from 1.2 to 6 bar, a pressure in the retentate outlet of from 1 to 6 bar and a pressure on the permeate side of the membrane of from 5.8 to 0.2 bar.

The cleaning operation per se is known from the abovedescribed literature and is based on the fact that, to a membrane electrode, a voltage is applied which is sufficiently high to electrolyze one of the liquids present in the mixture of substances to be filtered. Preferably, water is electrolyzed. At the membrane electrode, depending on whether the membrane electrode is used as anode or cathode, gas bubbles of hydrogen or oxygen are formed. However, it is also possible to cleave organic liquids at the membrane electrode into gaseous components.

By applying an electrical voltage the membrane electrode is charged and as a result of the electrical voltage, gas bubble development occurs on the membrane surface. As a result of the gas bubbles being formed, deposits on the surface of the membrane are dislodged. By means of the movement of the membrane electrode, it is possible in a simple manner to ensure that the solid particles detached from the membrane electrode surface are carried away from the membrane electrode. This process can be supported by the abovementioned pressure reversal and the resultant flow reversal.

The movement of the membrane electrode is preferably a rotation. By means of the centrifugal forces occurring during the rotation, currents are generated on the membrane electrode surface which transport the solid particles detached by the gas bubble development to the outsides of a rotating circular or virtually circular membrane electrode. The solid particles can be removed from the outsides of the membrane electrode, for example with the retentate stream. By means of the movement of the membrane electrode, in particular by the rotary movement of the membrane electrode, the cleaning of the membrane electrode surface by means of gas bubble development is markedly improved.

According to the invention, particularly preferably the membrane electrode rotates during the cleaning and the cleaning operation more slowly than during filtration and the filtration operation. Preferably, the membrane electrode rotates during cleaning at a speed of rotation of 0.1 to 5 min⁻¹. During the filtration operation, the membrane electrode preferably rotates at a speed of rotation of from 1 to 500 min⁻¹, very particularly preferably at a speed of rotation of from 100 to 300 min⁻¹.

However, it can also be advantageous if the membrane electrode rotates at the same speed during cleaning and during the filtration operation. Preference is given in this case to speeds of rotation of from 1 to 10 min⁻¹, preferably from 1 to 5 min⁻¹.

Preferably, for the cleaning operation, an electrical voltage greater than 1.5 V is applied between the membrane electrode and at least one corresponding counterelectrode. Preferably, a current or a voltage is applied of a magnitude which ensures that the current intensity at the counterelectrode is greater than 1 mA/cm², preferably greater than 10 mA/cm².

The electrical voltage can be applied in pulsed form or as a continuous voltage. Preferably a continuous voltage is used during the cleaning operation. By slow rotation of the stack, each point of the membrane surface experiences a pulsing electrical current, as a result of which the best cleaning effects are obtained. After, by means of the electrical cleaning of the membrane surface, the flux has increased back to the starting value or has at least been improved, the filtration is continued again in the normal operation without electric power. It can be advantageous to use a higher speed of rotation during filtration than during the cleaning operation.

By applying a voltage, in accordance with the abovedescribed principle, by means of the gas bubble development on the membrane surface, cleaning of the membrane occurs. Depending on the shape of counterelectrode used, the gas bubbles do not form, however, over the entire region of the membrane electrode surface. In order to achieve formation of gas bubbles on the entire membrane electrode surface, generally disk-shaped counterelectrodes must be present of the same size as the membrane electrode on both sides of the membrane electrode. This association considerably increases the expense of the electrofiltration process, since the counterelectrodes must have noble and expensive metals, in order that the counterelectrode, which is usually the anode, is dimensionally stable. As a result of the inventive rotation or movement of the membrane during the cleaning operation, however, it is now also possible to use counterelectrodes which have a smaller shape than the membrane electrode. It is only necessary in this case to ensure that each region of the membrane electrode is brought at least once during the cleaning operation to a sufficiently small distance from the counterelectrode. In the case of such an implementation of the inventive process, gas bubble development occurs in each case only in the region of the counterelectrodes, since here the electric field is greatest. To obtain complete cleaning of the entire membrane surface, the membrane electrodes are passed by the counterelectrodes by slow rotation of the membrane electrode stack.

The inventive process can also be used advantageously with dead-end filtration. With this filtration process it is not possible to achieve an adequately high overflow velocity of the liquid to be filtered over the membrane. The inventive process here offers the possibility of simulating or achieving an overflow velocity by means of the fact that the membrane electrode is moved according to the invention. Dead-end filtration is also preferably carried out at a feed pressure of from 1.2 to 6 bar and a pressure on the permeate side of the membrane of from 5.8 to 0.2 bar.

A suitable apparatus for carrying out the inventive process is particularly the inventive apparatus for electrofiltration. According to the invention, this apparatus, which is also termed hereinafter electrofiltration module, has at least one rotating membrane electrode and at least one counterelectrode. Preferably, the counterelectrode has a smaller surface area than the membrane electrode. By rotating the membrane electrode, all regions of the membrane electrode surface are passed by the counterelectrode.

According to the invention the membrane electrodes comprise an inorganic membrane which conducts the electrical current. Preferably, the membrane electrode comprises an inorganic membrane which was prepared on the basis of an interrupted electrically conducting support which has been provided with a titanium dioxide-containing coating which is permeable to inorganic material. The inventive membranes may preferably be negatively charged by applying an electrical current. Material-permeable in the meaning of the present invention means that the coating has pores. Depending on the application (filtration projects), membranes can be used which have suitable maximum pore sizes, so that particles which are greater than the maximum pore size are retained during filtration.

As membrane electrodes, according to the invention what are termed membrane pads are used which are arranged on an axle and are disk-shaped and preferably have a thickness of from 1 mm to 30 mm, particularly preferably from 1 mm to 10 mm. It is also possible to use thinner membrane pads, with restrictions being given in the dimensions owing to the necessary stability and/or separation efficiency. Preferably the membrane pads have a round or virtually round shape, the maximum diameter being from 10 to 100 cm, preferably from 10 to 50 cm. The membrane pads preferably have an orifice or bore hole in their center whose outer diameter is from 1 to 9 cm. The orifice or bore hole very particularly preferably has an outer diameter which corresponds to the outer diameter of the shaft or axle.

Suitable membranes for preparing the membrane pads used as membrane electrode are all membranes which are at least partially electrically conducting. Preferably, membranes of predominantly inorganic constituents are used, for example ceramic membranes or metal membranes. Production of such ceramic membranes is described, for example, in WO 99/15260, WO 99/15262 or WO 96/00198. Metal membranes can be, for example, metal nets or metal cloths. Very particularly preferably, inorganic membranes are used which are flexible and bendable.

The membrane pads are available, for example, by the means that at least one inorganic membrane, which preferably has at least partially electrically conducting properties, is fixed onto a porous support disk or a round or virtually round disk-shaped holder which has in the center a recess, preferably a round recess. The fixing can be performed, for example, by sticking. This takes place not only on the upper side but also on the lower side of the support disk. The outer rim of the support disk is either sealed or made impermeable using a suitable material, or also closed with an electrically conducting membrane. The inner rim of the disk is not sealed and not stuck to a membrane. In this manner membrane pads are obtained which are permeable on the flat sides only for those substances whose particle size is less than the pore size of the respective membrane used. The outer rim of the membrane pad is either just as permeable to substances as the side surfaces or completely impermeable. The inner rim of the membrane pad is permeable to all substances having a particle size less than the pore size of the porous support disk.

It can also be advantageous if the membrane pads are produced from membranes into which spacer materials, drainage materials or nonwoven web has been incorporated. Also, such membranes can be produced in accordance with WO 99/15260 and/or WO 99/15262 in which the spacer material, the drainage material or the nonwoven web required is used as porous support material onto which a porous ceramic layer is applied. Preferably, a porous ceramic layer is applied which has titanium oxide which can be made electrically conducting by applying a voltage. The membrane pads required can be obtained from such membranes, for example by punching, in which case the outer rims which would be permeable to materials after being punched out, must be sealed or welded with corresponding materials, for example glues or sealing glass.

It can be advantageous if the porous support disk and/or the spacer material, the drainage material or the nonwoven web is electrically conducting. However, this is not absolutely necessary provided that the membrane or membrane surface used is made electrically conducting.

Suitable counterelectrodes are in particular rod electrodes. However, differently shaped electrodes can also be used, for example disk electrodes or cake-slice shaped electrodes. According to the invention the counterelectrode has an equally sized shape or outline, or smaller shape or outline, preferably a smaller shape or outline, than the membrane electrode. Since the inventively used membrane electrodes preferably have circular or at least polygonal shapes or outlines, suitable counterelectrodes are particularly preferably electrodes which, as outline, have a circle section. Preferably, the circle section has the same outer radius as the outline of the membrane electrode. The circle section can have all sizes less than 360 degrees. Preferably the counterelectrode has a circle section (cake slice) of from 60 to 0.1 degrees. The abovementioned rod electrode can be considered to be a counterelectrode having a very small circle cross section.

Said counterelectrodes can, independently of their shape or outline, be produced from the materials customarily used for electrodes. Preferably, the counterelectrodes of the inventive apparatus are produced from Ti, Ir, Pt, Au, Pd or alloys which comprise these metals. It can also be advantageous to use standard electrodes coated with the abovementioned metals. The selection of standard electrodes is limited by the fact that the electrodes or the base bodies of the electrodes used must be dimensionally stable with respect to the solutions or mixtures of substances to be treated.

The inventive apparatus for electrofiltration can have one or more of the abovementioned membrane pads. Also, the inventive apparatus can have one or more of the abovementioned counterelectrodes. Preferably, the inventive electrofiltration module has a ratio of counterelectrodes to membrane pads of from 0.5 to 1 to 10 to 1. A ratio of 0.5 to 1 is achieved, for example, by arranging exactly one counterelectrode between two membrane pads.

The inventive electrofiltration module has at least one membrane pad which is arranged on at least one shaft which has at least in part openings in such a manner that the inner rim of the membrane pad lies over all openings of the shaft. It can be advantageous if not only one but a plurality of membrane pads are arranged on such a shaft. In this case, at least one opening of the shaft is covered in each case by the inner rim of a membrane pad. The membrane pads are fixed to the shaft. This can be done in a manner known to those skilled in the art, for example by welding or sticking. One condition for fixing the pads to the shaft is that it must be ensured that between the inner rim of the membrane pads and the shaft no interstitial spaces remain, through which substances can pass. Between the individual membrane pads on the shaft, interstitial spaces must be present which are of a size such that at least one counterelectrode can be arranged between two membrane pads. The distance of the membrane pads from one another is determined by the arrangement of the openings in the shaft. Against this background, the arrangement of the openings on the shaft is not of any desired type, but must meet said condition. It can be advantageous to provide spacers between the individual membrane pads. Such an arrangement of shaft and at least one membrane pad is designated hereinafter as a membrane electrode stack.

As shaft, electrically conducting hollow objects can be used which preferably have a round or square cross section, for example metal tubes. The abovementioned openings in the sides of the shafts must comply in their arrangement with the abovementioned condition that membrane pads which are arranged over the openings have a sufficiently great spacing. Through these openings the filtrate passing through the membrane of the membrane pads can be transferred into the shaft and through this shaft be passed to a vessel.

The inventive electrofiltration module preferably has at least one chamber which has at least one inlet and at least one outlet. In this chamber is, in addition, installed at least one membrane electrode stack. Preferably, the membrane electrode stack is installed in the chamber in such a manner that the membrane pads in operation of the electrofiltration module are arranged horizontally or vertically to the bottom surface of the chamber. Preferably, the membrane electrode stack is installed in the chamber in such a manner that the shaft rests in bearings which are integrated into the side walls of the chamber. On the shaft, preferably outside the chamber, is installed at least one drive which makes it possible to turn the shaft. Preferably, a motor is mounted on the shaft which permits the shaft to rotate at an adjustable speed.

If the inventive filtration module is used in a filtration according to the dead-end principle, the outlet of the chamber of the filtration module is closed during the filtration operation. The permeate, as in cross-flow filtration, is passed out of the filtration module through the shaft on which the membrane pads are arranged. During or after the cleaning process, the outlet from the chamber can be briefly opened in order to flush the cleaned-off particles from the chamber.

In the chamber is also situated at least one counterelectrode. Preferably, in the chamber there are at least so many counterelectrodes that the abovementioned ratio of counterelectrodes to membrane pads is complied with. Preferably, all counterelectrodes are connected to one another in an electrically conducting manner. It can be advantageous if, per membrane pad in the chamber, not only one counterelectrode is present, but at least two or more. When using more than one counterelectrode per membrane pad, it can be advantageous to arrange the counterelectrodes in such a manner that the angle between the counterelectrodes which are situated on a plane between the membrane pads is identical.

For stability reasons it can be advantageous to attach non-conducting shells to the top of some electrodes and to construct the counterelectrodes to be of such a length that the nonconducting shells lie on the shaft as bearing shells. In this manner the shaft can be supported in the interior of the chamber with an additional bearing.

The shaft and thus the membrane electrode stack and the counterelectrodes are connected to a power supply, more precisely in such a manner that the membrane electrode stack is connected to one pole and the counterelectrodes are connected to the other pole. The power supply delivers current at a voltage of at least 1.5 V. Direct current or alternating current can be used, preferably direct current is used. Very particularly preferably the direct current is used in such a manner that the membrane electrode stack is connected as cathode and the counterelectrodes are connected as anode.

It can be advantageous to install in a chamber not only one membrane electrode stack, but a plurality. Advantageously, all membrane electrode stacks are connected together as a cathode.

The inventive apparatus can be used to carry out the inventive process for increasing the filtration efficiency of membrane filtration systems in the filtration of mixtures of substances, for example according to the cross-flow or dead-end principle.

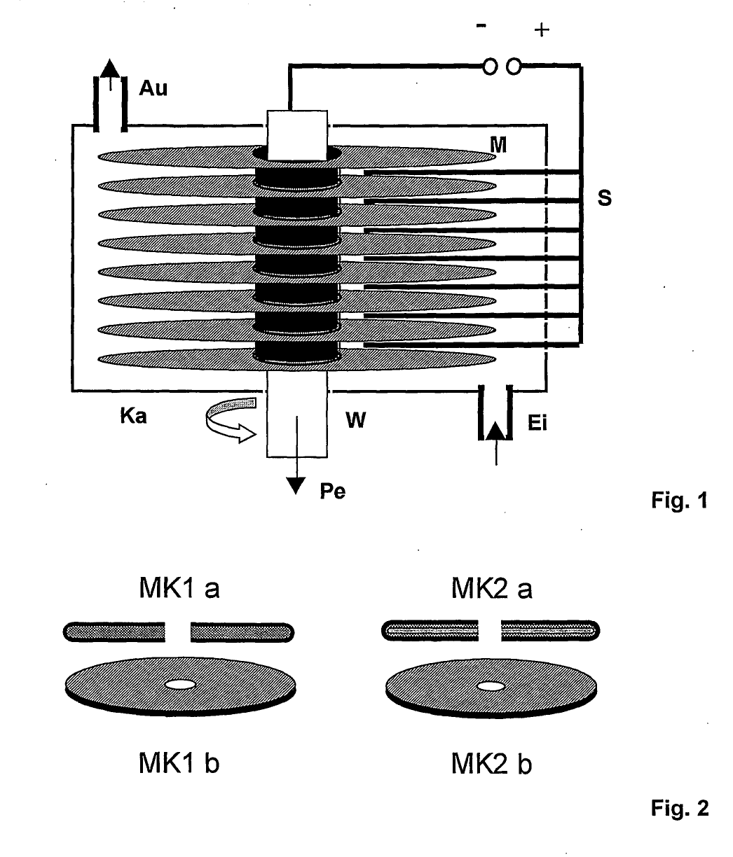

The inventive apparatus will be described in more detail with reference to the drawings FIGS. 1 to 4, without the inventive apparatus being restricted thereto.

FIG. 1 shows diagrammatically an inventive electrofiltration module. In a chamber Ka, which has an inlet Ei and an outlet Au there is a shaft W on which are arranged a plurality of membrane pads as membrane electrodes M. The membrane electrodes are electrically connected to the negative pole of the power supply (−) via the shaft W which is hollow and through which the permeate Pe can be removed. The shaft is mounted in such a manner that it can rotate. Between the membrane electrodes M are installed rod electrodes S which are electrically connected to one another and together are connected to the positive pole of the power supply (+).

FIG. 2 shows the inventive membrane pads diagrammatically. The views designated MK 1a and MK 2a, represent a section through an inventive membrane pad. The views designated MK 1b and MK 2b represent the membrane pads in plan view.

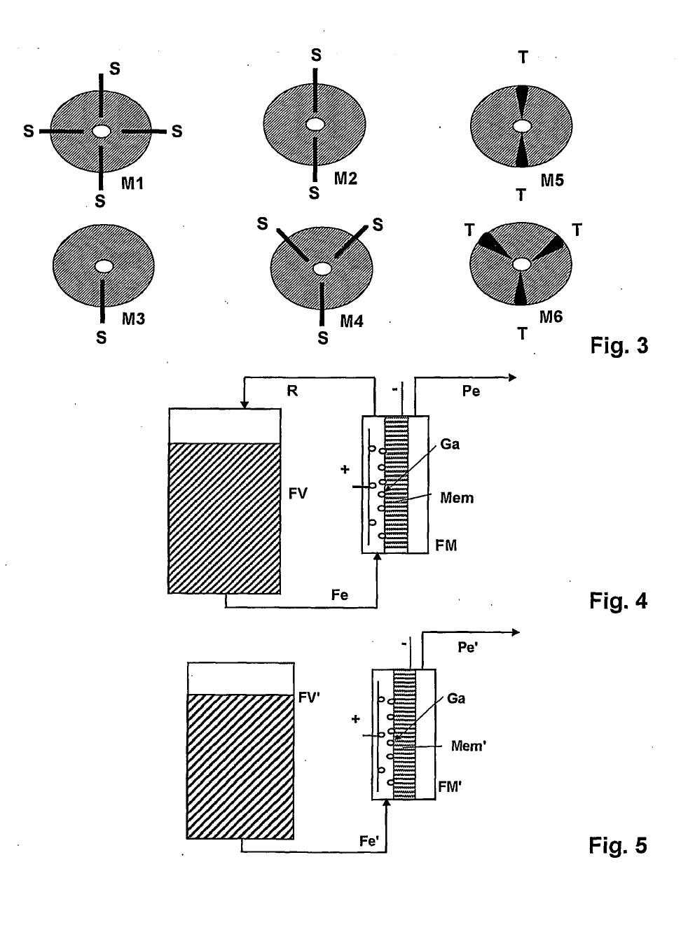

FIG. 3 shows by way of example four possible arrangements of rod electrodes S in comparison with the membrane electrodes M1 to M4. In addition, two possible arrangements of cake-slice shaped counterelectrodes T which have the outline of a circle section or ring section are shown by way of example in comparison with the membrane electrodes M5 and M6.

FIG. 4 shows the principle functioning of electrofiltration. In the electrofiltration as can also be carried out using the inventive electrofiltration module, a stream to be filtered is circulated through a filtration module FM. As a result of the differing pressure on the two sides of the filtration membrane, part of the feed stream Fe passes purified as permeate Pe through the filtration membrane Mem into the permeate chamber. The predominant part of the feed stream and the particles retained by the filtration membrane pass back as retentate R into the feed reservoir FV.

By applying a voltage to the membrane (−) and a counterelectrode (+) likewise present, as a result of electrolysis, gas development occurs at the membrane. Since the gas development Ga occurs directly at the membrane surface, particles which cover the membrane surface are detached from this and with sufficiently high flow through the filtration module are backwashed with the retentate into the feed reservoir. In this manner the membrane may be cleaned by applying a voltage to the membrane.

FIG. 5 shows the principle functioning of electrofiltration according to the dead-end principle. During electrofiltration, as can also be carried out using the inventive electrofiltration module, a stream to be filtered (feed) Fe′ is passed from the feed reservoir FV′ into a filtration module FM′. As a result of the differing pressure on the two sides of the filtration membrane Mem′, a part of the feed stream passes, purified as permeate Pe′, through the filtration membrane into the permeate chamber.

By applying a voltage to the membrane (−) and a counterelectrode (+) which is also present, as a result of electrolysis gas development Ga occurs at the membrane. Since the gas development occurs directly on the membrane surface, particles which cover the membrane surface are detached from this. In this manner the membrane may be cleaned by applying a voltage to the membrane.

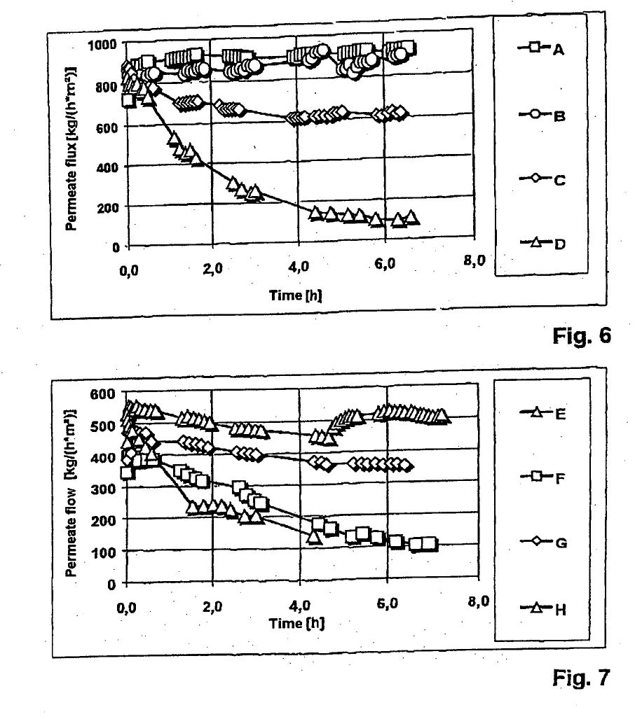

FIGS. 6 and 7 show in graph form the results of measurements obtained for the experiments described in the examples.

### EXAMPLE

### Electrofiltration of a 1% Strength PMMA Latex Solution

In an inventive filtration apparatus, an electrofiltration of a 1% strength polymethylmethacrylate (PMMA) latex was carried out at different speeds of rotation. The filtration apparatus had a membrane electrode having an outer diameter of 10 cm. The membrane used for producing the membrane electrode had a mean pore width of 0.08 μm. The counterelectrodes (anodes) used in the experiments A, B and E were two platinum-coated titanium rod electrodes having a round profile, a length of 10 cm and a diameter of 5 mm. The rod electrodes were arranged parallel to one another above and below the membrane electrode at a distance of 5 mm from the membrane electrode.

For comparison purposes, in experiment C a filtration was performed in which the experimental parameters were identical to those of experiment A except that power was not applied to the membrane electrode.

Likewise for comparison purposes, in experiment D disk electrodes were used as counterelectrodes. These were also platinum-coated titanium disks or rings which were in turn arranged above and below the membrane electrode at a distance of 5 mm in parallel to the membrane electrode. In contrast to the membrane electrode, the disk electrodes were fixed so as to be immovable.

Experiments E to H were carried out using the same apparatus and the same parameters as experiments A to D, except that another membrane electrode having a mean pore size of 0.075 μm was used. In experiment G, as in experiment B, measurements were made without power. The course of the measurement curves was correspondingly similar. Likewise the course of curves H and D corresponded. In both experiments the filtration was carried out with application of a direct current to the membrane electrode and to a disk electrode (circle section 360° ) as counterelectrode.

In experiment F, the electrodes used were cake-slice shaped electrodes having a circle section of in each case 180°, which were mounted congruently, in parallel above and below the membrane electrode. The speed of rotation was 10 min⁻¹.

In experiment E, at a speed of rotation of 1 min⁻¹, filtration was performed for a period of 4.5 hours firstly without applying an electric current. After this period a current of 2 A was applied.

The assignment of curves A to E to the experimental parameters can be taken from the table below.

| Measurement | | | |
|---|---|---|---|
| curve/ | Speed of | Current | |
| experiment | rotation | intensity | Electrode type |
| A | 1 min⁻¹ | 2 A | Rod electrode |
| B | 2 min⁻¹ | 2 A | Rod electrode |
| C | 1 min⁻¹ | Without power | |
| D | 0 min⁻¹ | 2 A | Disk electrode |
| E | 1 min⁻¹ | Without power, 2 A | Rod electrode |
| F | 10 min⁻¹ | 2 A | Cake-slice shaped |
| | | | electrode 180° |
| G | 10 min⁻¹ | Without power | |
| H | 10 min⁻¹ | 2 A | Disk electrode |

In FIG. 6, the time courses of the permeate flow during the experiment are plotted. As can be seen from the profiles of the graphs, the permeate flow over the experimental time of 6.5 hours was virtually constant in experiments A and B. The curve belonging to experiment C exhibits a continuous decrease in permeate flow in the course of the experimental time. It can be seen from the curve belonging to experiment D that the decrease in permeate flow over the experimental time is significantly greater with the experimental parameters chosen.

In FIG. 7, the time courses of the permeate flow over the experiment are plotted for experiments E to H. The lower permeate flow because of the lower maximum pore size of the membrane electrode used is clearly recognizable even at the beginning of the experiments. The course of the curve for experiment E corresponds, at the start of the course of the curve, to experiment F, that is to say the permeate flow decreases with experimental period. After 4.5 hours, that is to say the time point at which a current is applied to the membrane electrode, the permeate flow through the membrane increases again, and after half an hour virtually achieves again the value of permeate flux through the membrane at the start of the experiment. The use of a cake-slice shaped electrode having a circle section of 180° (curve F) shows a scarcely better filtration efficiency than the curve using the disk electrode (experiment E).

Curve G shows a similar course to curve B, which is not surprising, since both curves reflect the course of the permeate flow for filtration without electric power. The curves F and H are virtually identical and resemble the course of curve D. Carrying out filtration with a disk electrode (circle section 360°) or with a cake-slice shaped electrode (circle section 180°) shows scarcely any differences at a speed of rotation of 10 min⁻¹.

In contrast to the comparison experiment C in which the filtration is carried out without power and the permeate flow decreases continuously over the experimental period, the permeate flow in the case of the electrofiltrations according to experiment A or B remains virtually constant over the entire experimental period. This is due to the cleaning of the membrane by gas bubble development. Gas bubble development takes place in the case of experiment A at every position on the membrane electrode once per minute. In experiment B, gas bubble development, owing to the higher speed of rotation, takes place twice per minute, since every region of the membrane electrode comes twice per minute into the region of the electric field on the rod electrode in which the voltage is high enough to cleave the water of the PMMA solution electrolytically into hydrogen and oxygen.

In experiments H and D in which a disk electrode was used and thus at each region of the membrane electrode a voltage sufficiently high for the electrolysis of water was permanently applied, the constant gas bubble development leads to a much more rapid decrease in permeate flux. This phenomenon is assumed to be explained by the fact that the intense gas bubble development partially blocks the pores of the membrane electrodes which therefore no longer contribute to the filtration. The course of curve F in addition shows that when a cake-slice shaped electrode having a circle section of 180° and a speed of rotation of the membrane electrode of 10 min⁻¹ are used, gas bubble development still takes place semicontinuously and thus similarly poor filtration results are obtained to when a disk electrode is used. For this reason the use of electrodes which are not too large must be sought, or when large electrodes (circle section 180°) are used, the speed of rotation must be appropriately throttled.

From the course of the curve for experiment E, it may be seen that it is not absolutely necessary to apply a voltage to the membrane electrode or regions of the membrane electrode at regular intervals, even at the start of filtration. Rather, it can be sufficient if a voltage is applied to the membrane electrode or parts thereof only when a decrease in permeate flow to a certain limiting value has occurred.

1-23. cancel.

24. A process for electrofiltration in which a membrane electrode is cleaned by gas bubble development, comprising:
rotating the membrane electrode whereby each region of the membrane electrode is brought at least once during a cleaning operation to a sufficiently small distance from a counterelectrode.

25. The process as claimed in claim 24, further comprising charging the membrane electrode by applying an electrical voltage whereby an electrical voltage gas bubble development occurs on a surface of the membrane electrode.

26. The process as claimed in claim 25, wherein the electrical voltage is greater than 1.5 V.

27. The process as claimed in claim 25, wherein the electrical voltage is applied in pulsed form or as a continuous voltage.

28. The process as claimed in claim 25, wherein a current intensity at the membrane electrode is greater than 1 mA/cm².

29. The process as claimed in claim 24, wherein the membrane electrode rotates more slowly during the cleaning operation than during a filtration operation.

30. The process as claimed in claim 24, wherein the membrane electrode rotates at a same speed during the cleaning operation and during a filtration operation.

31. The process as claimed in claim 29, wherein the membrane electrode rotates during the cleaning operation at a speed of rotation of from 0.1 to 5 min⁻¹.

32. The process as claimed in claim 29, wherein the membrane electrode rotates during the filtration operation at a speed of rotation of from 1 to 500 min⁻¹.

33. The process as claimed in claim 32, wherein the membrane electrode rotates during the filtration operation at a speed of rotation of from 100 to 300 min⁻¹.

34. An apparatus for electrofiltration in which a membrane electrode is cleaned by gas bubble development, comprising:
at least one rotating membrane electrode and at least one counterelectrode and, by rotating the membrane electrode, all regions of the membrane electrode surface are passed by the counterelectrode.

35. The apparatus as claimed in claim 34, wherein the counterelectrode has a smaller shape or outline than the membrane electrode.

36. The apparatus as claimed in claim 34, wherein the membrane electrode comprises a membrane that conducts electrical current.

37. The apparatus as claimed in claim 36, wherein the membrane electrode comprises an inorganic membrane prepared on a basis of an interrupted electrically conducting support provided with a titanium oxide-containing coating permeable to inorganic material.

38. The apparatus as claimed in claim 36, wherein the membrane is configured to be charged by applying an electrical current.

39. The apparatus as claimed in claim 37, wherein the inorganic membrane is fixed to porous, round or virtually round disk-shaped supports to form membrane pads.

40. The apparatus as claimed in claim 39, wherein the disk-shaped supports are configured to be made of a plurality of layers.

41. The apparatus as claimed in claim 39, wherein the membrane pads have a bore hole in a center with an outer diameter from 1 cm to 9 cm.

42. The apparatus as claimed in claim 41, wherein an outer diameter of the membrane pads is from 10 to 100 cm.

43. The apparatus as claimed in claim 39, wherein the membrane pads are connected by a rotating shaft as a membrane cathode.

44. The apparatus as claimed in claim 34, wherein the at least one counterelectrode includes one or more dimensionally stable counterelectrodes arranged at least one of above and below the membrane electrode.

45. The apparatus as claimed in claim 44, wherein the counterelectrodes have at least one of materials Ti, Ir, Pt, Au, Pd, or mixtures and/or alloys of these.

46. The apparatus as claimed in claim 34, wherein the apparatus is configured to carry out an electrolysis of aqueous solutions.
